(19) United States
(12) Patent Application Publication
(10) Pub. No.: US 2024/0266468 A1
(43) Pub. Date: Aug. 8, 2024

(54) NANOROD LIGHT-EMITTING DEVICE, METHOD OF MANUFACTURING THE NANOROD LIGHT-EMITTING DEVICE, AND DISPLAY APPARATUS INCLUDING THE NANOROD LIGHTEMITTING DEVICE

(71) Applicant: SAMSUNG ELECTRONICS CO., LTD., Suwon-si (KR)

(72) Inventors: Joohun HAN, Suwon-si (KR); Junhee CHOI, Suwon-si (KR); Kiho KONG, Suwon-si (KR); Joosung KIM, Suwon-si (KR); Hyochul KIM, Suwon-si (KR); Eunsung LEE, Suwon-si (KR)

(73) Assignee: SAMSUNG ELECTRONICS CO., LTD., Suwon-si (KR)

(21) Appl. No.: 18/408,236

(22) Filed: Jan. 9, 2024

(30) Foreign Application Priority Data
Feb. 8, 2023 (KR) 10-2023-0016944

(51) Int. Cl. H01L 33/24; H01L 25/075; H01L 33/00; H01L 33/10; H01L 33/22; H01L 33/32; H01L 33/44

(52) U.S. Cl. CPC H01L 33/24; H01L 25/0753; H01L 33/0075; H01L 33/0095; H01L 33/10; H01L 33/22; H01L 33/32; H01L 33/44

(57) ABSTRACT

Provided is a nanorod light-emitting device having improved luminous efficiency by reducing surface defects. The nanorod light-emitting device includes a semiconductor light-emitting structure having a nanorod shape, a surface activation layer provided on a sidewall of the semiconductor light-emitting structure, and an epitaxial passivation layer provided on the surface activation layer.

### CROSS-REFERENCE TO RELATED APPLICATION

This application is based on and claims priority under 35 U.S.C. § 119 to Korean Patent Application No. 10-2023-0016944, filed on Feb. 8, 2023, in the Korean Intellectual Property Office, the disclosure of which is incorporated by reference herein in its entirety.

### BACKGROUND

### 1. Field

Embodiments of the disclosure relate to a nanorod light-emitting device and a method of manufacturing the nanorod light-emitting device, and more particularly, a nanorod light-emitting device having improved luminous efficiency, a method of manufacturing the nanorod light-emitting device, and a display apparatus including the nanorod light-emitting device.

### 2. Description of the Related Art

Light-emitting diodes (LEDs) are known as next-generation light sources having advantages, such as long life span, low power consumption, fast response speed, and environmental friendliness, compared to existing or related art light sources. Due to these advantages, there has been an increase in demand for the LEDs in various areas and products. For example, LEDs are commonly applied to various products, such as lighting apparatuses and backlights of display apparatuses.

Recently, micro- or nano-sized subminiature LEDs using Group Il-VI or Ill-V compound semiconductors have been developed. In addition, micro LED displays in which subminiature LEDs are directly applied as light-emitting elements of display pixels have been developed. However, when LEDs are miniaturized in micro or nano units, the luminous efficiency of the LEDs may decrease due to surface defects.

### SUMMARY

Provided is a nanorod light-emitting device with improved luminous efficiency.

Provided is a method of manufacturing a nanorod light-emitting device to reduce surface defects.

Provided is a display apparatus including a nanorod light-emitting device.

Additional aspects will be set forth in part in the description which follows and, in part, will be apparent from the description, or may be learned by practice of the presented embodiments of the disclosure.

According to an aspect of the disclosure, there is provided a nanorod light-emitting device including: a semiconductor light-emitting structure having a nanorod shape; a surface activation layer provided on a sidewall of the semiconductor light-emitting structure; and an epitaxial passivation layer provided on the surface activation layer.

The surface activation layer may be plasma-treated and configured to have surface roughness in a range of about 5 Å to about 50 Å.

The surface activation layer may have a thickness in a range of about 1 nm to about 5 nm.

The surface activation layer may include InGaN and AlN.

The epitaxial passivation layer may have a lattice matching epitaxy relationship or a domain matching epitaxy relationship with the semiconductor light-emitting structure.

The epitaxial passivation layer may include at least one of ZrO, SrO, MgO, BaO, CeO2, Gd2O3, CaO, HfO2, TiO2, AlOₓ, BaN, SiN, TiN, CeN, AlN, ZnSe, ZnS, AlGaN, or AlxGa1−xAs (x≥0.9).

The epitaxial passivation layer may have a thickness in a range of about 5 nm to about 20 nm.

The nanorod light-emitting device may further include an amorphous passivation layer on the epitaxial passivation layer.

The amorphous passivation layer may have a thickness in a range of about 20 nm to about 70 nm.

The epitaxial passivation layer may be configured to have a roughness in a range of about 5 Å to about 50 Å.

The nanorod light-emitting device may further include a distributed Bragg reflective layer on the epitaxial passivation layer.

The semiconductor light-emitting structure may include a first semiconductor layer doped to a first conductivity type, an emission layer provided on the first semiconductor layer, and a second semiconductor layer provided on the emission layer and doped to a second conductivity type different from the first conductivity type.

According to another aspect of the disclosure, there is provided a display apparatus including: a plurality of pixel electrodes; a common electrode corresponding to the plurality of pixel electrodes; and a plurality of nanorod light-emitting devices connected between the plurality of pixel electrodes and the common electrode, wherein each of the plurality of nanorod light-emitting devices includes: a semiconductor light-emitting structure having a nanorod shape; a surface activation layer provided on a sidewall of the semiconductor light-emitting structure; and an epitaxial passivation layer provided on the surface activation layer.

According to another aspect of the disclosure, there is provided a method of manufacturing a nanorod light-emitting device, the method including: forming, on a substrate, a first semiconductor layer doped to a first conductivity type; forming an emission layer on the first semiconductor layer; forming, on the emission layer, a second semiconductor layer doped to a second conductivity type different from the first conductivity type; forming a plurality of semiconductor light-emitting structures by patterning the first semiconductor layer, the emission layer, and the second semiconductor layer into a plurality of nanorod shapes; forming a surface activation layer on sidewalls of the plurality of semiconductor light-emitting structures; and forming an epitaxial passivation layer on the surface activation layer.

The forming of the surface activation layer may include: performing a precursor flow operation, a first purge supply operation, a reactant flow operation, and a second purge supply operation one or more times; and performing a plasma process after performing the precursor flow operation, the first purge supply operation, the reactant flow operation, and the second purge supply operation one or more times.

The performing of the plasma process may use an argon (Ar) plasma method, an N2 plasma method, or an NH3 plasma method.

The forming of the epitaxial passivation layer may include: an operation of depositing a material of the epitaxial passivation layer using an atomic layer deposition method; heating and crystallizing the deposited material of the epitaxial passivation layer; and repeating the depositing of the material of the epitaxial passivation layer and the crystallizing of the deposited material of the epitaxial passivation layer a plurality of times.

The surface activation layer may have a thickness in a range of about 1 nm to about 5 nm.

The surface activation layer may include InGaN and AlN.

The operation of depositing the material of the epitaxial passivation layer may be performed in range of 1 to 15 times.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view showing a schematic configuration of a nanorod light-emitting device according to an embodiment;

FIG. 2 is a plan view of the nanorod light-emitting device shown in FIG. 1;

FIGS. 3A to 3E are cross-sectional views showing a method of manufacturing the nanorod light-emitting device shown in FIG. 1 according to an embodiment;

FIG. 4 is a flowchart showing a process of forming a passivation layer according to an embodiment;

FIG. 5 is a cross-sectional view showing a schematic configuration of a nanorod light-emitting device according to another embodiment;

FIG. 6 is a cross-sectional view showing a schematic configuration of a nanorod light-emitting device according to another embodiment;

FIG. 7 shows breakdown voltage measurement results for the presence and absence of a surface activation layer;

FIG. 8 shows a comparison of passivation layer structures of an embodiment and a comparative example;

FIG. 9 is a cross-sectional view showing a schematic configuration of a nanorod light-emitting device according to another embodiment;

FIG. 10 is a conceptual diagram schematically showing a configuration of a display apparatus according to an embodiment, which uses a nanorod light-emitting device;

FIG. 11 is a block diagram of an electronic device according to an embodiment;

FIG. 12 shows an example in which a display apparatus according to an embodiment is applied to a mobile device;

FIG. 13 shows an example in which a display apparatus according to an embodiment is applied to a vehicle display apparatus;

FIG. 14 shows an example in which a display apparatus according to an embodiment is applied to augmented reality glasses or virtual reality glasses;

FIG. 15 shows an example in which a display apparatus according to an embodiment is applied to signage; and

FIG. 16 shows an example in which a display apparatus according to an embodiment is applied to a wearable display.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a nanorod light-emitting device, a method of manufacturing the nanorod light-emitting device, and a display apparatus including the nanorod light-emitting device will be described in detail with reference to the accompanying drawings. Like reference numerals in the drawings denote like components, and sizes of components in the drawings may be exaggerated for convenience of explanation. In addition, embodiments to be described below are only exemplary and various modifications from such embodiments may be possible.

Hereinafter, the term “on” or “above” may include not only one directly above another in contact but also one directly above another without contact. Singular expressions include plural expressions unless they are explicitly and differently specified in context. In addition, when a portion includes a component, a case may mean further including other components without excluding other components unless otherwise described.

The use of the term “above” and similar indicative terms may correspond to both singular and plural. When there is no explicit description or contrary description of operations constituting a method, these operations may be performed in an appropriate order, and may not be necessarily limited to the described order.

Also, in the specification, the term “units” or “ . . . modules” denote units or modules that process at least one function or operation, and may be realized by hardware, software, or a combination of hardware and software.

Connections of lines between components or connection members illustrated in the drawings exemplarily represent functional connection and/or physical or circuitry connections, and in a real apparatus, may be implemented by replaceable or additional various functional connections, physical connections, or circuitry connections.

The use of all examples or example terms is simply for describing a technical idea in detail, and the scope of the disclosure is not limited by these examples or example terms unless limited by the claims.

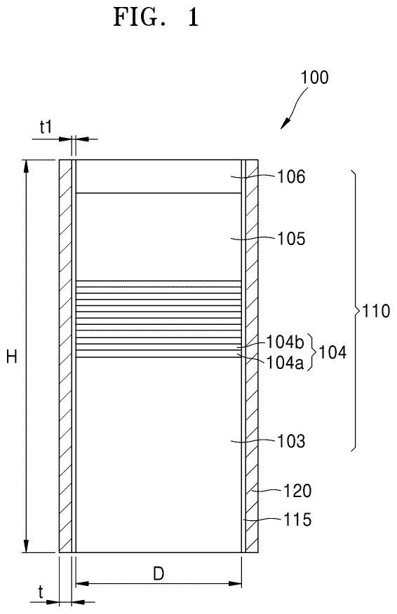

FIG. 1 is a cross-sectional view showing a schematic configuration of a nanorod light-emitting device according to an embodiment. Referring to FIG. 1, a nanorod light-emitting device 100 according to an embodiment may include a semiconductor light-emitting structure 110 having a nanorod shape, a surface activation layer 115 provided on a sidewall of the semiconductor light-emitting structure 110, and an epitaxial passivation layer 120 provided on the surface activation layer 115.

The semiconductor light-emitting structure 110 may include a first semiconductor layer 103, an emission layer 104 provided on the first semiconductor layer 103, and a second semiconductor layer 105 provided on the emission layer 104. The semiconductor light-emitting structure 110 may further include a transparent electrode 106 provided on the second semiconductor layer 105. According to an embodiment, the semiconductor light-emitting structure 110 may further include a transparent contact layer provided between the second semiconductor layer 105 and the transparent electrode 106.

The first semiconductor layer 103 and the second semiconductor layer 105 may include a Group Il-VI or Group Ill-V compound semiconductor material. The first semiconductor layer 103 and the second semiconductor layer 105 provide electrons and holes to the emission layer 104. To this end, the first semiconductor layer 103 may be doped n-type or p-type, and the second semiconductor layer 105 may be doped to a conductivity type electrically opposite to that of the first semiconductor layer 103. For example, the first semiconductor layer 103 may be doped n-type and the second semiconductor layer 105 may be doped p-type. In another example, the first semiconductor layer 103 may be doped p-type and the second semiconductor layer 105 may be doped n-type. In the case of n-type doping of the first semiconductor layer 103 or the second semiconductor layer 105, silicon (Si) may be used as a dopant, and in the case of p-type doping of the first semiconductor layer 103 or the second semiconductor layer 105, zinc (Zn) may be used as a dopant. The first semiconductor layer 103 or the second semiconductor layer 105, doped n-type, may provide electrons to the emission layer 104 and the second semiconductor layer 105 or the first semiconductor layer 103, doped p-type, may provide holes to the emission layer 104.

The emission layer 104 has a quantum well structure in which quantum wells are provided between barriers. Light may be generated as electrons and holes provided from the first semiconductor layer 103 and the second semiconductor layer 105 recombine in the quantum well in the emission layer 104. A wavelength of light emitted from the emission layer 104 may be determined according to an energy bandgap of a material constituting the quantum well in the emission layer 104. According to an embodiment, the emission layer 104 may have only one quantum well. However, the disclosure is not limited thereto, and as such the emission layer 104 may have a multi-quantum well (MQW) structure in which a plurality of quantum wells 104B and a plurality of barriers 104A are alternately arranged as shown in FIG. 1. The thickness of the emission layer 104 or the number of quantum wells in the emission layer 104 may be appropriately selected by considering the driving voltage and luminous efficiency of the nanorod light-emitting device 100. For example, the thickness of the emission layer 104 may be selected to be less than twice a diameter D of the semiconductor light-emitting structure 110.

The semiconductor light-emitting structure 110 may have a nanorod shape having a nanoscale or microscale size. For example, the semiconductor light-emitting structure 110 may have a diameter D in a range of about 0.05 μm to about 2 μm. The semiconductor light-emitting structure 110 having a nanorod shape may have a uniform or a substantially uniform diameter in a height direction. For example, diameters of the first semiconductor layer 103, the emission layer 104, the second semiconductor layer 105, and the transparent electrode 106 may be same or may be substantially the same. According to an embodiment, the length between the lower surface of the first semiconductor layer 103 and the upper surface of the transparent electrode 106 may be referred to as a height H of the semiconductor light-emitting structure 110, and the height H of the semiconductor light-emitting structure 110 may be in a range of about 0.3 μm to about 20 μm. In addition, the semiconductor light-emitting structure 110 may have a large aspect ratio of, for example, 5 or more. According to another embodiment, the length between the lower surface of the first semiconductor layer 103 and the upper surface of the second semiconductor layer 105 may be referred to as the height H of the semiconductor light-emitting structure 110, and the height H of the semiconductor light-emitting structure 110 may be in a range of about 0.3 μm to about 20 μm. According to an embodiment, the diameter D of the semiconductor light-emitting structure 110 may be 600 nm and the height H of the semiconductor light-emitting structure 110 may be 5 μm. In this case, the aspect ratio of the semiconductor light-emitting structure 110 (e.g., the ratio of the height H to diameter D) is slightly greater than 8.

However, when the semiconductor light-emitting structure 110 having a large aspect ratio is manufactured in such a small size, the surface area to volume ratio increases and surface defects of the emission layer 104 increase. In otherwords, surface defects due to dangling bonds generate on the outer surface of the emission layer 104, and as the surface area to volume ratio increases, the number of dangling bonds also increases, and thus, surface defects also increase. These surface defects impede the flow of current and become a factor that lowers the luminous efficiency of the emission layer 104.

The surface activation layer 115 may improve the crystallinity of the epitaxial passivation layer 120. The surface activation layer 115 may activate the surface of the semiconductor light-emitting structure 100 before depositing the epitaxial passivation layer 120 to remove surface contaminants through surface modification, thereby increasing the effect of the epitaxial passivation layer 120.

The epitaxial passivation layer 120 may include an insulating crystal material having the same crystal structure as that of the semiconductor light-emitting structure 100. The epitaxial passivation layer 120 may have a lattice matching epitaxy relationship or a domain matching epitaxy relationship with the semiconductor light-emitting structure 110. The lattice matching epitaxy relationship means a relationship in which the lattice constant of the epitaxial passivation layer 120 is identical or substantially identical to the lattice constant of the semiconductor light-emitting structure 110. In addition, the domain matching epitaxy relationship means a relationship in which the lattice constant of the epitaxial passivation layer 120 is identical or substantially identical to an integer multiple of the lattice constant of the semiconductor light-emitting structure 110 or the lattice constant of the semiconductor light-emitting structure 110 is identical or substantially identical to an integer multiple of the lattice constant of the epitaxial passivation layer 120. According to an embodiment, the lattice constant of the epitaxial passivation layer 120 does not have to be identical to the lattice constant of the semiconductor light-emitting structure 110 or an integer multiple of the lattice constant of the semiconductor light-emitting structure 110. Instead, the lattice constant of the epitaxial passivation layer 120 may be within a somewhat similar range as the lattice constant of the semiconductor light-emitting structure 110 or an integer multiple of the lattice constant of the semiconductor light-emitting structure 110. For example, the difference between a lattice constant m1 of the semiconductor light-emitting structure 110 and a lattice constant m2 of the epitaxial passivation layer 120 may be within ±30% of the lattice constant m1 of the semiconductor light-emitting structure 110. That is, the difference may be (˜30%×m1)≤(m1−m2)≤(30%×m1). Alternatively, the difference between an integer multiple n of the lattice constant m1 of the semiconductor light-emitting structure 110 and the lattice constant m2 of the epitaxial passivation layer 120 may be within ±30% of the integer multiple n of the lattice constant m1 of the semiconductor light-emitting structure 110. That is, the difference may be (˜30%×m1×n)≤(m1×n)−m2≤(30%×m1×n).

The surface activation layer 115 is provided between the semiconductor light-emitting structure 110 and the epitaxial passivation layer 120, and thus, atoms located on the outer surface of the semiconductor light-emitting structure 110 may be combined with atoms of the surface activation layer 115. In addition, the arrangement of atoms in the surface activation layer 115 may help atoms of the epitaxial passivation layer 120 be arranged epitaxially. As the crystallinity of the epitaxial passivation layer 120 increases, dangling bonds on the outer surface of the semiconductor light-emitting structure 110 are reduced and surface defects are reduced. Therefore, current may relatively flow uniform in the entire area of the emission layer 104 and light emission may occur relatively uniform in the entire area of the emission layer 104. Accordingly, the luminous efficiency of the nanorod light-emitting device 100 may increase.

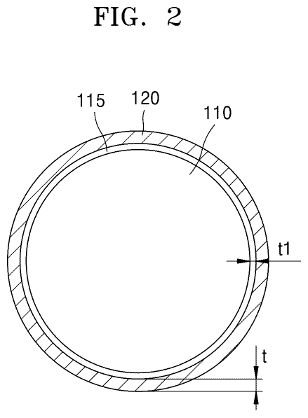

FIG. 2 is a plan view of the nanorod light-emitting device 100 shown in FIG. 1. The surface activation layer 115 may be placed in direct contact with the epitaxial passivation layer 120. In addition to reducing surface defects on the outer surface of the semiconductor light-emitting structure 110, the epitaxial passivation layer 120 may also protect the semiconductor light-emitting structure 110 from external physical and chemical impacts and insulate the semiconductor light-emitting structure 110 to prevent leakage of current. The surface activation layer 115 and the epitaxial passivation layer 120 may be provided to completely surround sidewalls of the semiconductor light-emitting structure 110. Accordingly, the surface activation layer 115 and the epitaxial passivation layer 120 may each have a ring shape in a plan view, and may have a cylindrical shape as a whole. In FIG. 2, the semiconductor light-emitting structure 110 is illustrated as having a circular shape, However, the disclosure is not limited thereto, and as such, according to another embodiment, the semiconductor light-emitting structure 110 may have another shape, such as a square shape.

Referring to FIGS. 1 and 2, thickness t1 of the surface activation layer 115 along the diameter of the nanorod light-emitting device 100 may be in a range of about 1 nm to about 5 nm. Moreover, a thickness t of the epitaxial passivation layer 120, that is, the distance between the inner sidewall and the outer sidewall of the epitaxial passivation layer 120, may be in a range of about 5 nm to about 20 nm.

In addition, the energy bandgap of the epitaxial passivation layer 120 may be greater than the energy bandgap of the semiconductor light-emitting structure 110, and thus, electrons and holes may be confined within the semiconductor light-emitting structure 110. For example, the energy bandgap of the epitaxial passivation layer 120 may be greater than the energy bandgap of the emission layer 104, and thus, electrons and holes may be confined within the emission layer 104 and thus light may be easily generated from the emission layer 104. The epitaxial passivation layer 120 may include at least one of, for example, ZrO, SrO, MgO, BaO, CeO₂, Gd₂O₃, CaO, HfO₂, TiO₂, AlOₓ, BaN, SiN, TiN, CeN, AlN, ZnSe, ZnS, AlGaN, and AlₓGa₁₋ₓAs (x≥0.9).

The epitaxial passivation layer 120 may have a thickness in a range of about 5 nm to about 20 nm and have the same crystal structure as the semiconductor light-emitting structure 110 in each of a horizontal plane and a vertical plane. Here, the horizontal plane represents a cross-section in the diameter D direction in FIG. 1, and the vertical plane represents a cross-section in the height H direction in FIG. 1.

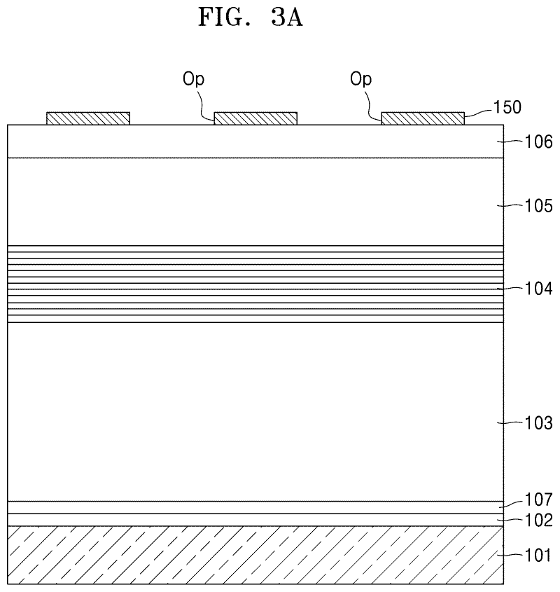

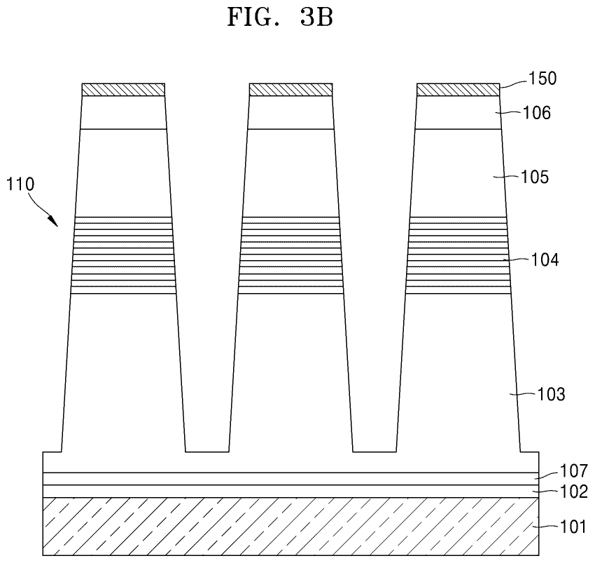

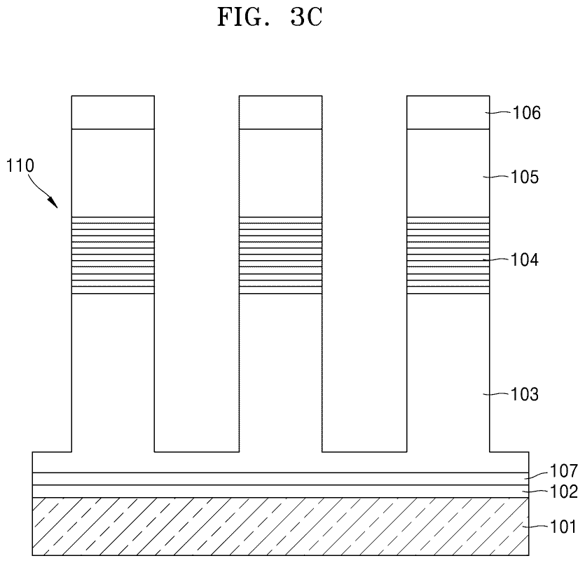

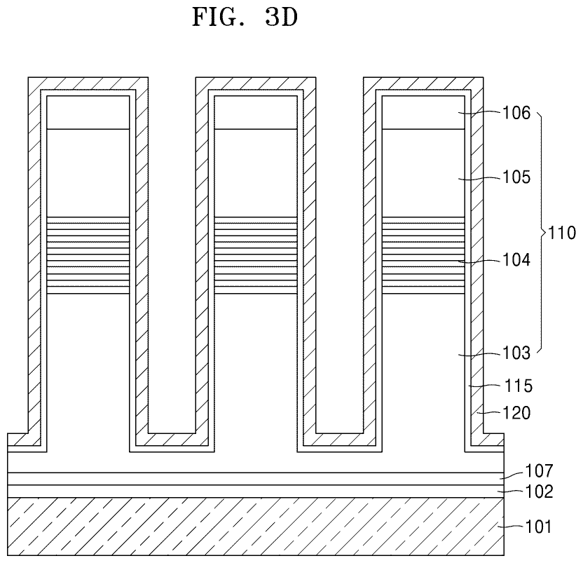

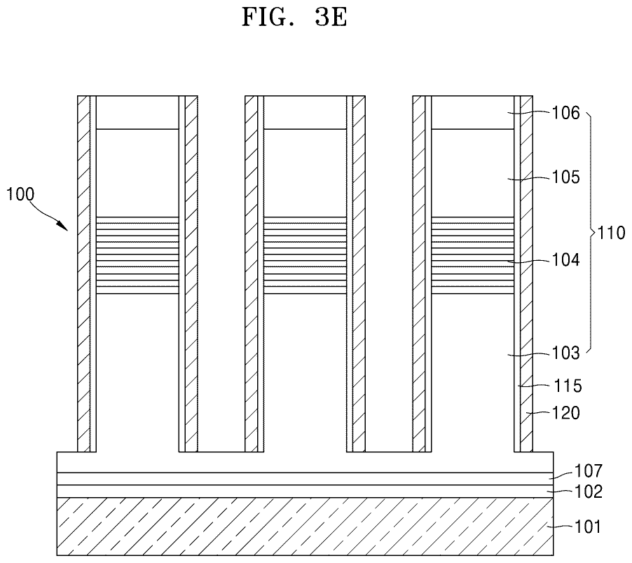

FIGS. 3A to 3E are cross-sectional views showing a method of manufacturing the nanorod light-emitting device 100 shown in FIG. 1 according to an embodiment.

Referring to FIG. 3A, a buffer layer 102, a first semiconductor layer 103, an emission layer 104, a second semiconductor layer 105, and a transparent electrode 106 are sequentially grown on a substrate 101. The buffer layer 102 is provided over a large area of the upper surface of the substrate 101, the first semiconductor layer 103 is grown on the entire upper surface of the buffer layer 102, and the emission layer 104 is grown on the entire upper surface of the first semiconductor layer 103. In addition, the second semiconductor layer 105 and the transparent electrode 106 may each be grown to be provided over the entire upper surface of a layer thereunder.

The substrate 101 and the buffer layer 102 may include, for example, sapphire or GaAs. The substrate 101 and the buffer layer 102 may be doped to the same conductivity type as the first semiconductor layer 103 thereon. For example, when the first semiconductor layer 103 is doped n-type, the substrate 101 and the buffer layer 102 may also be doped n-type. The substrate 101 may be doped at a lower concentration than the buffer layer 102, and the buffer layer 102 may be doped at a higher concentration than the substrate 101. A contact layer 107 for ohmic contact may be further provided between the buffer layer 102 and the first semiconductor layer 103. In this case, the buffer layer 102, the contact layer 107, the first semiconductor layer 103, the emission layer 104, the second semiconductor layer 105, and the transparent electrode 106 are sequentially grown on the substrate 101. For example, the contact layer 107 may include GaInP or GaAs, or include both GaInP and GaAs. The contact layer 107 may be doped to the same conductivity type as the first semiconductor layer 103 and may be doped at a higher doping concentration than those of the buffer layer 102 and the first semiconductor layer 103. According to an embodiment, a contact layer may be further provided between the second semiconductor layer 105 and the transparent electrode 106.

When the nanorod light-emitting device 100 is a light-emitting device that generates red light, the first semiconductor layer 103 may include, for example, n-AlGaInP, and the second semiconductor layer 105 may include p-AlGaInP. Therefore, the first semiconductor layer 103 is a single layer including a semiconductor material of a single composition, and the second semiconductor layer 105 is also a single layer including a semiconductor material of the same single composition as that of the first semiconductor layer 103. However, the first semiconductor layer 103 and the second semiconductor layer 105 are doped in opposite conductivity types. For example, the first semiconductor layer 103 may be doped with Si and the second semiconductor layer 105 may be doped with Zn. Depending on the emission color of the nanorod light-emitting device 100, the materials of the first semiconductor layer 103 and the second semiconductor layer 105 may include other semiconductor materials, such as InGaN or AlGaInN, in addition to AlGaInP.

The emission layer 104 may include, for example, AlGaInP in the case of generating red light, and AlGaInP of the emission layer 104 is undoped. The emission layer 104 includes a barrier layer and a quantum well layer, and for this purpose, the content of Al in AlGaInP may vary. For example, the barrier layer has a higher Al content in AlGaInP than the quantum well layer. In addition, among the barrier layer, the quantum well layer, the first semiconductor layer 103 and the second semiconductor layer 105, the first semiconductor layer 103 and the second semiconductor layer 105 have the highest Al content, the barrier layer in the emission layer 104 has the next highest Al content, and the quantum well layer in the emission layer 104 has the lowest Al content. For example, the Al content of the first semiconductor layer 103 and the second semiconductor layer 105, is higher than the Al content of the barrier layer, and the AL content of the barrier layer is higher than the A content of the quantum well layer. Accordingly, in a conduction band, the energy level of the first semiconductor layer 103 and the second semiconductor layer 105 is the highest, the energy level of the barrier layer in the emission layer 104 is next highest, and the energy level of the quantum well layer in the emission layer 104 is the lowest. Even when using a semiconductor material other than AlGaInP, the emission layer 104 may be formed to have a barrier layer and a quantum well layer by adjusting the composition of the material thereof.

According to an embodiment, after the transparent electrode 106 is formed, a hard mask 150 having a plurality of openings Op arranged at regular intervals is formed on the transparent electrode 106. For example, after the material of the hard mask 150 is entirely deposited on the upper surface of the transparent electrode 106, the material of the hard mask 150 may be patterned to have a plurality of openings Op arranged at regular intervals by using a lithography method, thereby forming the hard mask 150. For example, the hard mask 150 may include a single layer of SiO₂ or a double layer of SiO₂/Al. Although not illustrated in the cross-sectional view of FIG. 3A, when viewed from the top, the hard mask 150 may have a plurality of openings two-dimensionally arranged.

Referring to FIG. 3B, regions not covered by the hard mask 150 may be etched and removed using a dry etching method. For example, by sequentially etching the transparent electrode 106, the second semiconductor layer 105, the emission layer 104, and the first semiconductor layer 103 under the openings of the hard mask 150, the transparent electrode 106, the second semiconductor layer 105, the emission layer 104, and the first semiconductor layer 103 may be patterned in the form of a plurality of nanorods. Then, as shown in FIG. 3B, a plurality of semiconductor light-emitting structures 110 having nanorod shapes may be formed over the substrate 101, the buffer layer 102, and the contact layer 107 all at once. According to an embodiment, each of the plurality of semiconductor light-emitting structures 110 including the transparent electrode 106, the second semiconductor layer 105, the emission layer 104, and the first semiconductor layer 103 may be formed over the substrate 101, the buffer layer 102, and the contact layer 107 all at once. Although a lower region of the first semiconductor layer 103 is partially left (or partially remain) in FIG. 3B according to an embodiment, the disclosure is not limited thereto, and as such, according to another embodiment etching may be performed until the contact layer 107 is exposed. In this case, the lower region of the first semiconductor layer 103 is completely etched, and the contact layer 107 may partially remain.

The semiconductor light-emitting structures 110 in FIG. 3B may each have a shape in which a diameter gradually decreases in a height direction from the first semiconductor layer 103 to the transparent electrode 106. Referring to FIG. 3C, the diameters of the semiconductor light-emitting structures 110 may be made uniform in the height direction through a wet process using a KOH (potassium hydroxide) solution. In this process, the hard mask 150 may also be removed.

Referring to FIG. 3D, the surface activation layer 115 and the epitaxial passivation layer 120 may be formed to a uniform thickness on the surfaces of the semiconductor light-emitting structures 110. The surface activation layer 115 may be formed using an atomic layer deposition (ALD) method.

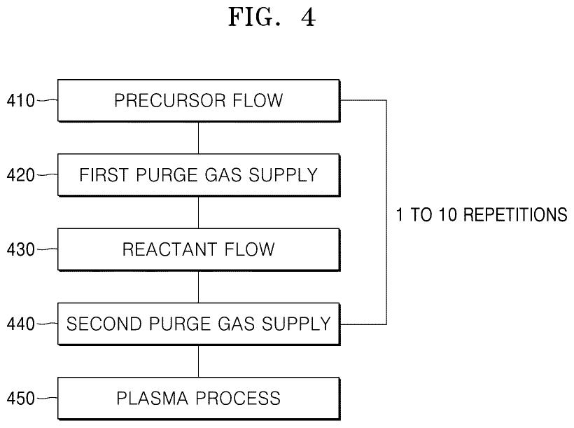

FIG. 4 shows a process of forming the surface activation layer 115 according to an embodiment.

According to an embodiment, a method of forming the surface activation layer 115 may include a precursor flow operation 410, a first purge operation 420, a reactant flow operation 430, and a second purge operation 440. According to an embodiment, the precursor flow operation 410, the first purge operation 420, the reactant flow operation 430, and the second purge operation 440 may be repeated. For example, the precursor flow operation 410, the first purge operation 420, the reactant flow operation 430, and the second purge operation 440 may be repeated between 1 to 10 times. According to an embodiment, the reactant flow operation 430 may include a plasma process. For example, the plasma process may be used in the reactant flow operation 430 depending on required conditions. The plasma process may include, for example, any one of Ar plasma, N₂ plasma, and NH₃ plasma.

According to an embodiment, after repeating the precursor flow operation 410, the first purge operation 420, the reactant flow operation 430, and the second purge operation 440, the method may include a plasma process 450 for inducing thermal baking by plasma activation.

The surface activation layer 115 is a layer for improving the performance of the epitaxial passivation layer 120 and may activate the surface of a base material (e.g., InGaN) before a passivation process. Because part of the surface of the base material is damaged or oxidized after dry etching and wet etching processes, a sufficient passivation layer effect may not be obtained when passivation is performed immediately in the state in which part of the surface of the base material is damaged or oxidized.

In this state, the surface of the base material is plasma-treated with one of Ar, N₂, and NH₃, and the plasma treatment may be performed for 10 seconds or more and 300 seconds or less. In this way, by forming the surface activation layer 115, defects on the surface of the base material are removed to have a surface condition suitable for depositing a passivation layer.

After the surface activation operation is completed, a passivation layer is deposited. As a passivation layer, AlN will be described as an example.

According to an embodiment, a one cycle process includes supplying a precursor to the surface activation layer, supplying a first purge gas to remove a first by-product, supplying a reactant, and supplying a second purge gas to remove a second by-product. After the one cycle process, a thermal baking process is performed with Ar plasma. An epitaxial passivation layer is formed through the above process. During the thermal baking process using Ar plasma, RF power of about 100 W to about 600 W and time of about 1 seconds to about 60 seconds may be applied.

In order to form the epitaxial passivation layer 120 on the surface activation layer 115, a process of depositing an epitaxial passivation layer material several times by using, for example, an ALD method and then heating and crystallizing the deposited passivation layer material may be repeatedly performed.

The passivation layer material may be repeatedly deposited within 1 to 15 times by using the ALD method. Although it may vary depending on the passivation layer material, the thickness of the deposited passivation layer material may increase by about 0.5 nm per one deposition. Then, the deposited passivation layer material may be crystallized by heating the deposited passivation layer material. For example, the deposited passivation layer material may be crystallized using an argon (Ar) plasma method. Then, until the thickness of the crystallized epitaxial passivation layer 120 reaches a target thickness, the process of depositing the passivation layer material and the process of crystallizing the deposited passivation layer material may be repeated within 1 to 10 times.

According to this method, the crystallized epitaxial passivation layer 120 may be formed surrounding the surface of the semiconductor light-emitting structure 110 and accordingly, the crystallized epitaxial passivation layer 120 reduces damage to the semiconductor light-emitting structure 110 and improves crystallinity. During the process of depositing the passivation layer material, the number of depositions may be determined by considering the thickness of the passivation layer material that may be crystallized by an Ar plasma method without damaging the semiconductor light-emitting structure 110. In addition, the number of repetitions of the process of depositing the passivation layer material and the process of crystallizing the deposited passivation layer material may be determined according to the target thickness of the crystallized epitaxial passivation layer 120.

Referring to FIG. 3E, a portion of an epitaxial passivation layer 120 present between adjacent semiconductor light-emitting structures 110 and a portion of an epitaxial passivation layer 120 present on the upper surface of the semiconductor light-emitting structure 110 may be removed Then, only an epitaxial passivation layer 110 surrounding the sidewalls of the plurality of semiconductor light-emitting structures 120 may remain. In this way, a plurality of nanorod light-emitting devices 100 may be formed at once on the substrate 101, the buffer layer 102, and the contact layer 107. After that, the plurality of nanorod light-emitting devices 100 may be individually separated by removing the buffer layer 102. Alternatively, by cutting the substrate 101 and the buffer layer 102 in a longitudinal direction, each nanorod light-emitting device 100 may be used in a state where both the substrate 101 and the buffer layer 102 are attached to each nanorod light-emitting device 100. Alternatively, two or more nanorod light-emitting devices 100 may be used together by cutting the substrate 101 and the buffer layer 102 in the longitudinal direction so that two or more nanorod light-emitting devices 100 remain.

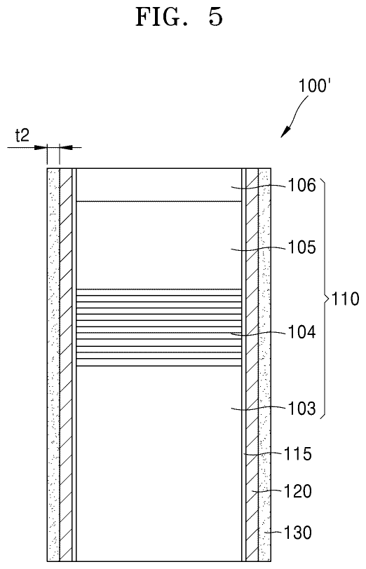

FIG. 5 shows an example in which a passivation layer 130 is further provided in the nanorod light-emitting device shown in FIG. 1. Referring to FIG. 5, a nanorod light-emitting device 100′ may further include a passivation layer 130 provided on the epitaxial passivation layer 120. Components having the same reference numerals as those in FIG. 1 have substantially the same configuration as those in FIG. 1, and thus, detailed descriptions thereof are omitted.

The passivation layer 130 may be an amorphous layer. The passivation layer 130 may protect the crystallized epitaxial passivation layer 120. The thickness t2 of the passivation layer 130 that is an amorphous passivation layer may be in a range of about 20 nm to about 70 nm. The passivation layer 130 may include at least one of, for example, ZrO, SrO, MgO, BaO, CeO₂, Gd₂O₃, CaO, HfO₂, TiO₂, AlOₓ, BaN, SiN, TiN, CeN, AlN, ZnSe, ZnS, AlGaN, and AlₓGa₁₋ₓAs (x≥0.9). The passivation layer 130 may include a material that is the same as or different from that of the epitaxial passivation layer 120.

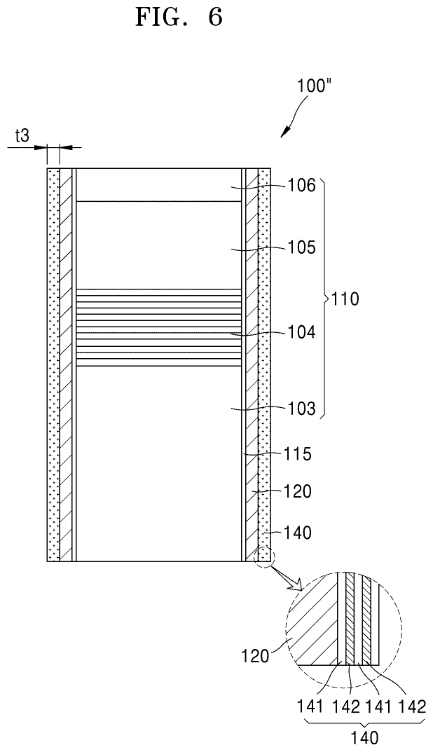

FIG. 6 shows an example in which a distributed Bragg reflective layer 140 is further provided in the nanorod light-emitting device shown in FIG. 1. Referring to FIG. 6, a nanorod light-emitting device 100″ may further include the distributed Bragg reflective layer 140 provided on the epitaxial passivation layer 120.

The distributed Bragg reflective layer 140 may be formed by alternately stacking a plurality of times a first layer 141 having a first refractive index and a second layer 142 having a second refractive index different from the first refractive index. Due to the difference in refractive index, all reflected waves at the interface of each layer may interfere. The distributed Bragg reflective layer 140 may have a structure in which, for example, layers including two of Si, Si₃N₄, SiO₂, TiO₂, Ta₂O₅, and ZrO₂ are alternately stacked. The distributed Bragg reflective layer 140 may have a structure in which, for example, SiO₂ layers and TiO₂ layers are alternately stacked. Light reflectance may be controlled by the thickness t3 of the distributed Bragg reflection layer 140 and/or a number of layers of the two layers of the distributed Bragg reflection layer 140. According to an embodiment, the thickness t3 of the distributed Bragg reflection layer 140 may be equal to or greater than the epitaxial passivation layer 120.

The distributed Bragg reflective layer 140 may have a structure in which, for example, one to seven pairs of the first layer 141 and the second layer 142 are stacked. Because the distributed Bragg reflective layer 140 may selectively reflect the wavelength of light emitted from the emission layer 104, the light extraction efficiency of the semiconductor light-emitting structure 110 may increase by lowering the reflectance of light having a desired wavelength.

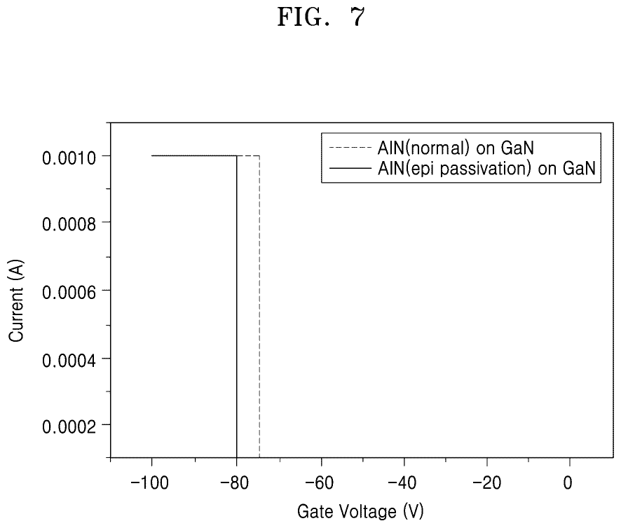

FIG. 7 shows a result of measuring a breakdown voltage of a nanorod light-emitting device according to an embodiment. The solid line indicates the case (i.e., AlN (epi passivation) on GaN) where the surface activation layer 115 is present in an AlN on GaN structure, and the dashed line indicates the case (i.e., AlN (normal) on GaN) where there is no surface activation layer. The solid line indicates the case where the epitaxial passivation layer is formed using Ar plasma. In this case, the insulation property of the epitaxial passivation layer is good, and as a result, leakage current is reduced.

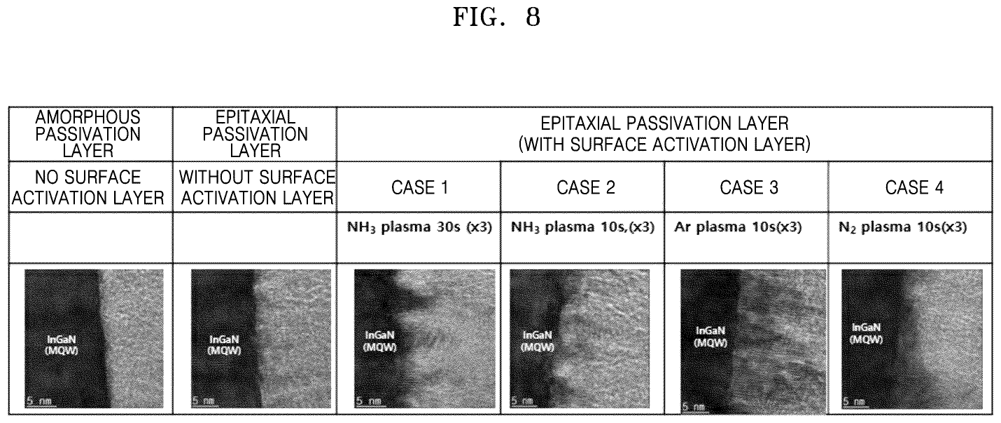

FIG. 8 shows an amorphous passivation layer structure by a normal process without a plasma process, a structure having an epitaxial passivation layer without a surface activation layer, and a structure having an epitaxial passivation layer with a surface activation layer. For the structure with a surface activation layer, the case (Case 1) where NH₃ plasma treatment is performed for 30 seconds, the case (Case 2) where NH₃ plasma treatment is performed for 10 seconds, the case (Case 3) where Ar plasma treatment is performed for 10 seconds, and the case (Case 4) where N₂ plasma treatment is performed for 10 seconds are shown. Crystallinity of the epitaxial passivation layer is relatively good in the structure with a surface activation layer (e.g., compared to the structure without a surface activation layer.

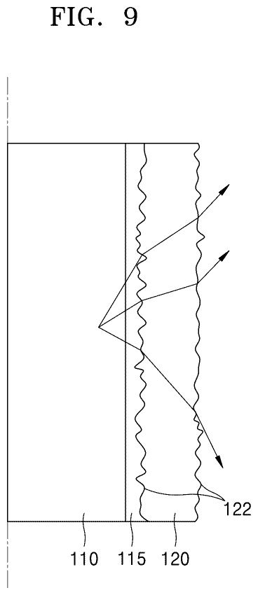

As shown in FIG. 9, the epitaxial passivation layer 120 of a nanorod light-emitting device according to an embodiment may have a rough surface, that is, roughness 122. For example, the roughness 122 of the epitaxial passivation layer 120 may be in a range of about 5 Å to about 50 Å. In this way, when the epitaxial passivation layer 120 has roughness, light emission efficiency may increase by increasing the efficiency of extracting light emitted from the nano light-emitting structure to the outside. According to an embodiment, the surface activation layer 115 may have a roughness corresponding to the epitaxial passivation layer 120, and the roughness of the surface activation layer 115 may be in a range of about 5 Å to about 50 Å.

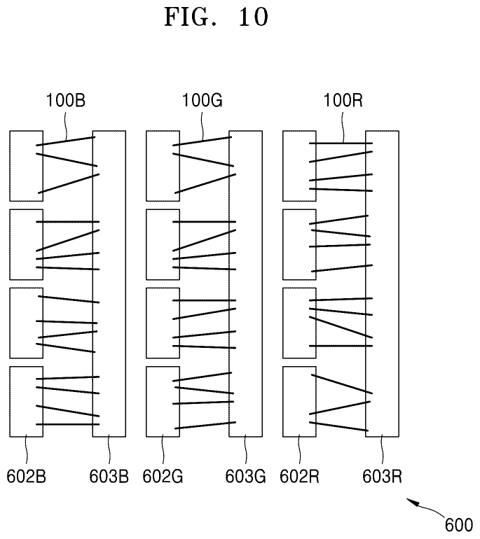

The nanorod light-emitting devices 100, 100′, and 100″ described above may be used in various applications. The nanorod light-emitting devices 100, 100′, and 100″ may be used as light-emitting elements of pixels of a next-generation display apparatus. For example, FIG. 10 is a conceptual diagram schematically showing a configuration of a display apparatus 600 according to an embodiment, which uses a nanorod light-emitting device.

Referring to FIG. 10, the display apparatus 600 may include a plurality of first pixel electrodes 602B, a first common electrode 603B corresponding to the plurality of first pixel electrodes 602B, a plurality of second pixel electrodes 602G, a second common electrode 603G corresponding to the plurality of second pixel electrodes 602G, a plurality of third pixel electrodes 602R, a third common electrode 603R corresponding to the plurality of third pixel electrodes 602R, a plurality of first nanorod light-emitting devices 100B connected between the first pixel electrodes 602B and the first common electrode 603B, a plurality of second nanorod light-emitting devices 100G connected between the second pixel electrodes 602G and the second common electrode 603G, and a plurality of third nanorod light-emitting devices 100R connected between the third pixel electrodes 602R and the third common electrode 603R.

For example, the first nanorod light-emitting devices 100B may be configured to emit blue light, the second nanorod light-emitting devices 100G may be configured to emit green light, and the third nanorod light-emitting devices 100R may be configured to emit green light. In addition, one first pixel electrode 602B may constitute one blue sub-pixel together with the first common electrode 603B, one second pixel electrode 602G may constitute one green sub-pixel together with the second common electrode 603G, and one third pixel electrode 602R may constitute one red sub-pixel together with the third common electrode 603R.

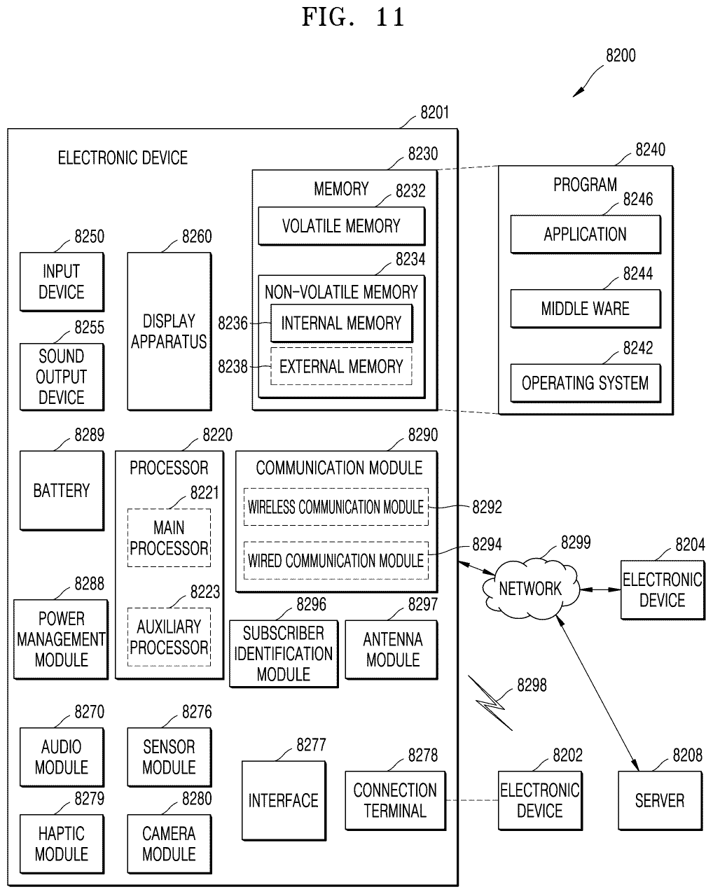

The nanorod light-emitting devices 100, 100′, and 100″ according to the embodiments described above may be applied to display apparatuses of various sizes and for various purposes without limitation. For example, FIGS. 11 to 16 show various devices including a display apparatus to which nanorod light-emitting devices according to an embodiment are applied.

FIG. 11 is a block diagram of an electronic device 8201 according to an embodiment. Referring to FIG. 11, the electronic device 8201 may be provided in a network environment 8200. In the network environment 8200, the electronic device 8201 may communicate with another electronic device 8202 through a first network 8298 (a short-range wireless communication network, etc.) or with another electronic device 8204 and/or a server 8208 through a second network 8299 (a remote wireless communication network, etc.). The electronic device 8201 may communicate with the electronic device 8204 through the server 8208. The electronic device 8201 may include a processor 8220, a memory 8230, an input device 8250, a sound output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. The electronic device 8201 may omit some of these components or may further include other components. Some of these components may be implemented as an integrated circuit. For example, the sensor module 8276 (a fingerprint sensor, an iris sensor, an illuminance sensor, etc.) may be embedded in the display apparatus 8260 (a display, etc.)

The processor 8220 may execute software (a program 8240, etc.) to control one or more components (hardware, software, etc.) of the electronic device 8201 connected to the processor 8220 and to perform various data processing or computation operations. As part of the data processing or computation operations, the processor 8220 may be configured to load a command and/or data received from other components (the sensor module 8276, the communication module 8290, etc.) into a volatile memory 8232, process the command and/or the data stored in the volatile memory 8232, and store resulting data in a non-volatile memory 8234. The non-volatile memory 8234 may include an internal memory 8236 mounted in the electronic device 8201 and a removable external memory 8238. The processor 8220 may include a main processor 8221 (a central processing unit, an application processor, etc.) and an auxiliary processor 8223 (a graphics processing unit, an image signal processor, a sensor-hub processor, a communication processor, etc.) which may operate separately from or together with the main processor 8221. The auxiliary processor 8223 may use less power than the main processor 8221 and may perform specialized functions.

The auxiliary processor 8223 may operate instead of the main processor 8221, when the main processor 8221 is in an inactive state (a sleep state), may operate together with the main processor 8221, when the main processor 8221 is in an active state (an application execution state), and may control a function and/or a state associated with one or more components (the display apparatus 8260, the sensor module 8276, the communication module 8290, etc.) of the electronic device 8201. The auxiliary processor 8223 (the image signal processor, the communication processor, etc.) may be implemented as part of other functionally related components (the camera module 8280, the communication module 8290, etc.).

The memory 8230 may store various pieces of data required by the components (the processor 8220, the sensor module 8276, etc.) of the electronic device 8201. The data may include, for example, software (the program 8240, etc.), and input data and/or output data with respect to a command related to the software. The memory 8230 may include the volatile memory 8232 and/or the non-volatile memory 8234.

The program 8240 may be stored in the memory 8230 as software and may include an operating system 8242, middleware 8244, and/or an application 8246.

The input device 8250 may receive a command and/or data to be used for the components (the processor 8220, etc.) of the electronic device 8201, from the outside (a user, etc.) of the electronic device 8201. The input device 8250 may include a remote controller, a microphone, a mouse, a keyboard, and/or a digital pen (a stylus pen, etc.).

The sound output device 8255 may output a sound signal to the outside of the electronic device 8201. The sound output device 8255 may include a speaker and/or a receiver. The speaker may be used for a general purpose, such as reproducing multimedia content or recording content, and the receiver may be used to receive an incoming call. The receiver may be integrated as part of the speaker or separately provided from the speaker.

The display apparatus 8260 may visually provide data to the outside of the electronic device 8201. The display apparatus 8260 may include a display, a hologram device, or a control circuit configured to control a projector and a corresponding device. The display apparatus 8260 may include a driving circuit, a micro semiconductor light-emitting device, a side reflection structure, a bottom reflection structure, and the like. The display apparatus 8260 may further include touch circuitry configured to sense a touch operation and/or sensor circuitry (a pressure sensor, etc.) configured to measure the intensity of a force generated by the touch operation.

The audio module 8270 may convert sound into an electrical signal or an electrical signal into sound. The audio module 8270 may obtain sound via the input device 8250 or may output sound via the sound output device 8255 and/or a speaker and/or headphones of another electronic device (the electronic device 8102, etc.) directly or wirelessly connected to the electronic device 8201.

The sensor module 8276 may sense an operation state (power, temperature, etc.) of the electronic device 8201 or an external environmental state (a user state, etc.) and generate electrical signals and/or data values corresponding to the sensed state. The sensor module 8276 may include a gesture sensor, a gyro-sensor, an atmospheric sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols to be used for the electronic device 8201 to be directly or wirelessly connected to another electronic device (the electronic device 8102, etc.). The interface 8277 may include a high-definition multimedia interface (HDMI) interface, a universal serial bus (USB) interface, a secure digital (SD) card interface, and/or an audio interface.

A connection terminal 8278 may include a connector, through which the electronic device 8201 may be physically connected to another electronic device (the electronic device 8102, etc.). The connection terminal 8278 may include an HDMI connector, a USB connector, an SD card connector, and/or an audio connector (a headphone connector, etc.).

The haptic module 8279 may convert an electrical signal into a mechanical stimulus (vibration, motion, etc.) or an electrical stimulus which is recognizable to a user via haptic or motion sensation. The haptic module 8279 may include a motor, a piezoelectric device, and/or an electrical stimulus device.

The camera module 8280 may capture a still image and a video. The camera module 8280 may include a lens assembly including one or more lenses, image sensors, image signal processors, and/or flashes. The lens assemblies included in the camera module 8280 may collect light emitted from an object, an image of which is to be captured.

The power management module 8288 may manage power supplied to the electronic device 8201. The power management module 8288 may be realized as part of a power management integrated circuit (PMIC).

The battery 8289 may supply power to the components of the electronic device 8201. The battery 8289 may include a non-rechargeable primary battery, a rechargeable secondary battery, and/or a fuel battery.

The communication module 8290 may support establishment of direct (wired) communication channels and/or wireless communication channels between the electronic device 8201 and other electronic devices (the electronic device 8202, the electronic device 8204, the server 8208, etc.) and communication performance through the established communication channels. The communication module 8290 may include one or more communication processors separately operating from the processor 8220 (an application processor, etc.) and supporting direct communication and/or wireless communication. The communication module 8290 may include a wireless communication module 8292 (a cellular communication module, a short-range wireless communication module, a global navigation satellite system (GNSS) communication module), and/or a wired communication module 8294 (a local area network (LAN) communication module, a power line communication module, etc.). From these communication modules, a corresponding communication module may communicate with other electronic devices through the first network 8298 (a short-range wireless communication network, such as Bluetooth, Wifi direct, or infrared data association (IrDa)) or the second network 8299 (a remote communication network, such as a cellular network, the Internet, or a computer network (e.g., a LAN, a WAN, etc.)). Various types of communication modules described above may be integrated as a single component (a single chip, etc.) or realized as a plurality of components (a plurality of chips). The wireless communication module 8292 may identify and authenticate the electronic device 8201 within the first network 8298 and/or the second network 8299 by using subscriber information (international mobile subscriber identification (IMSI), etc.) stored in the subscriber identification module 8296.

The antenna module 8297 may transmit a signal and/or power to the outside (other electronic devices, etc.) or receive the same from the outside. The antenna module 8297 (ok?) may include an emitter including a conductive pattern formed on a substrate (a printed circuit board (PCB), etc.). The antenna module 8297 may include an antenna or a plurality of antennas. When the antenna module 8297 includes a plurality of antennas, an appropriate antenna which is suitable for a communication method used in the communication networks, such as the first network 8298 and/or the second network 8299, may be selected. Through the selected antenna, signals and/or power may be transmitted or received between the communication module 8290 and other electronic devices. In addition to the antenna, another component (a radio frequency integrated circuit (RFIC), etc.) may be included in the antenna module 8297.

Some of the components of the electronic device 8201 may be connected to one another and exchange signals (commands, data, etc.) with one another, through communication methods performed among peripheral devices (a bus, general purpose input and output (GPIO), a serial peripheral interface (SPI), a mobile industry processor interface (MIPI), etc.).

The command or the data may be transmitted or received between the electronic device 8201 and another external electronic device, that is, the electronic device 8204, through the server 8208 connected to the second network 8299. The other electronic devices 8202 and 8204 may be electronic devices that are homogeneous or heterogeneous types with respect to the electronic device 8201. All or part of operations performed in the electronic device 8201 may be performed by one or more of the other electronic devices (the electronic devices 8202 and 8204 and the server 8208). For example, when the electronic device 8201 has to perform a function or a service, instead of directly performing the function or the service, the one or more other electronic devices may be requested to perform part or all of the function or the service. The one or more other electronic devices receiving the request may perform an additional function or service related to the request and may transmit a result of the execution to the electronic device 8201. To this end, cloud computing, distribution computing and/or client-server computing techniques may be used.

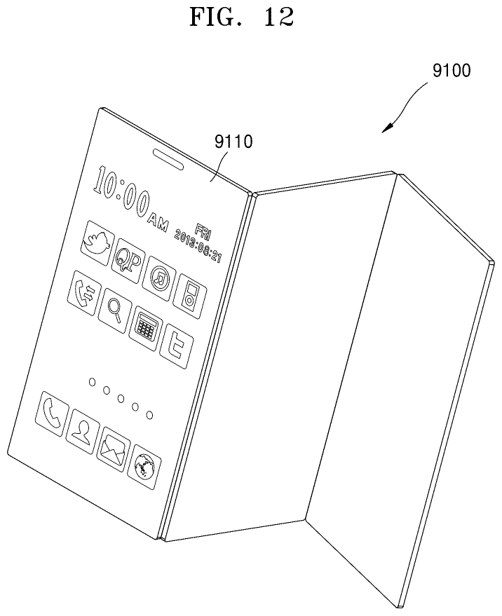

FIG. 12 shows an example in which a display apparatus according to an embodiment is applied to a mobile device 9100. The mobile device 9100 may include a display apparatus 9110, and the display apparatus 9110 may include the driving circuit, the micro semiconductor light-emitting device, the side reflection structure, the bottom reflection structure, and the like, which are described above. The display apparatus 9110 may have a foldable structure, for example, a multi-foldable structure.

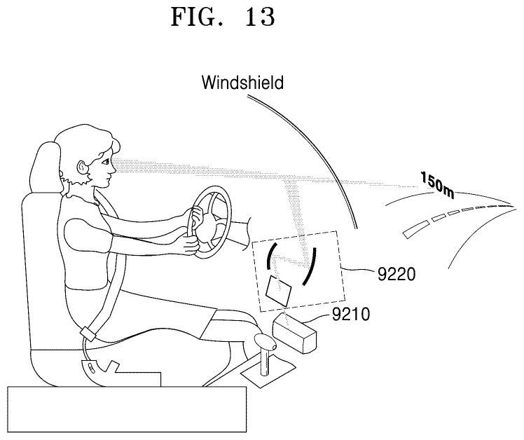

FIG. 13 shows an example in which a display apparatus according to an embodiment is applied to a vehicle display apparatus. The display apparatus may be a head-up display apparatus 9200 for a vehicle, and may include a display 9210 provided in an area of the vehicle, and a light path-changing member 9220 for changing light path for a driver to see an image generated by the display 9210.

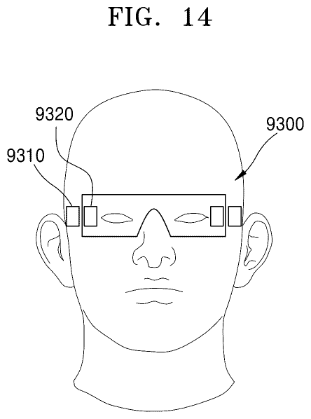

FIG. 14 shows an example in which a display apparatus according to an embodiment is applied to augmented reality glasses or virtual reality glasses. Augmented reality glasses 9300 may include a projection system 9310 for forming an image, and an element 9320 for guiding an image from the projection system 9310 to enter the user's eye. The projection system 9310 may include the driving circuit, the micro semiconductor light-emitting device, the side reflection structure, the bottom reflection structure, and the like, which are described above.

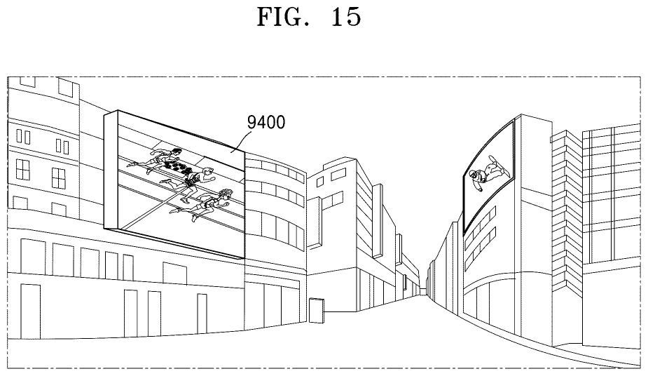

FIG. 15 shows an example in which a display apparatus according to an embodiment is applied to signage 9400. The signage 9400 may be used for outdoor advertisements using a digital information display and may control advertisement content and the like through a communication network. The signage 9400 may be implemented, for example, through the electronic device described with reference to FIG. 11.

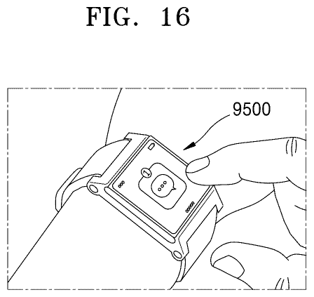

FIG. 16 shows an example in which a display apparatus according to an embodiment is applied to a wearable display 9500. The wearable display 9500 may include the driving circuit, the micro semiconductor light-emitting device, the side reflection structure, the bottom reflection structure, and the like, which are described above, and may be implemented through the electronic device described with reference to FIG. 11.

A display apparatus according to an embodiment may be applied to various other products, such as a rollable TV and a stretchable display.

According to the embodiments, a passivation layer of the nanorod light-emitting device has the same crystal structure as that of the semiconductor light-emitting structure. Accordingly, dangling bonds on the outer surface of the semiconductor light-emitting structure may be reduced due to the passivation layer, and thus, surface defects may be reduced. As a result, the luminous efficiency of the nanorod light-emitting device may increase.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A nanorod light-emitting device comprising:
a semiconductor light-emitting structure having a nanorod shape;
a surface activation layer provided on a sidewall of the semiconductor light-emitting structure; and
an epitaxial passivation layer provided on the surface activation layer.

2. The nanorod light-emitting device of claim 1, wherein the surface activation layer is plasma-treated and configured to have surface roughness in a range of about 5 Å to about 50 Å.

3. The nanorod light-emitting device of claim 1, wherein the surface activation layer has a thickness in a range of about 1 nm to about 5 nm.

4. The nanorod light-emitting device of claim 1, wherein the surface activation layer comprises InGaN and AlN.

5. The nanorod light-emitting device of claim 1, wherein the epitaxial passivation layer has a lattice matching epitaxy relationship or a domain matching epitaxy relationship with the semiconductor light-emitting structure.

6. The nanorod light-emitting device of claim 1, wherein the epitaxial passivation layer comprises at least one of ZrO, SrO, MgO, BaO, CeO₂, Gd₂O₃, CaO, HfO₂, TiO₂, AlOₓ, BaN, SiN, TiN, CeN, AlN, ZnSe, ZnS, AlGaN, or AlₓGa₁₋ₓAs (x≥0.9).

7. The nanorod light-emitting device of claim 1, wherein the epitaxial passivation layer has a thickness in a range of about 5 nm to about 20 nm.

8. The nanorod light-emitting device of claim 1, further comprising an amorphous passivation layer on the epitaxial passivation layer.

9. The nanorod light-emitting device of claim 8, wherein the amorphous passivation layer has a thickness in a range of about 20 nm to about 70 nm.

10. The nanorod light-emitting device of claim 1, wherein the epitaxial passivation layer is configured to have a roughness in a range of about 5 Å to about 50 Å.

11. The nanorod light-emitting device of claim 1, further comprising a distributed Bragg reflective layer on the epitaxial passivation layer.

12. The nanorod light-emitting device of claim 1, wherein the semiconductor light-emitting structure comprises:
a first semiconductor layer doped to a first conductivity type;
an emission layer provided on the first semiconductor layer; and
a second semiconductor layer provided on the emission layer and doped to a second conductivity type different from the first conductivity type.

13. A display apparatus comprising:
a plurality of pixel electrodes;
a common electrode corresponding to the plurality of pixel electrodes; and
a plurality of nanorod light-emitting devices connected between the plurality of pixel electrodes and the common electrode,
wherein each of the plurality of nanorod light-emitting devices comprises:
a semiconductor light-emitting structure having a nanorod shape;
a surface activation layer provided on a sidewall of the semiconductor light-emitting structure; and
an epitaxial passivation layer provided on the surface activation layer.

14. A method of manufacturing a nanorod light-emitting device, the method comprising:
forming, on a substrate, a first semiconductor layer doped to a first conductivity type;
forming an emission layer on the first semiconductor layer;
forming, on the emission layer, a second semiconductor layer doped to a second conductivity type different from the first conductivity type;
forming a plurality of semiconductor light-emitting structures by patterning the first semiconductor layer, the emission layer, and the second semiconductor layer into a plurality of nanorod shapes;
forming a surface activation layer on sidewalls of the plurality of semiconductor light-emitting structures; and
forming an epitaxial passivation layer on the surface activation layer.

15. The method of claim 14, wherein the forming of the surface activation layer comprises:
performing a precursor flow operation, a first purge supply operation, a reactant flow operation, and a second purge supply operation one or more times; and
performing a plasma process after performing the precursor flow operation, the first purge supply operation, the reactant flow operation, and the second purge supply operation one or more times.

16. The method of claim 14, wherein the performing of the plasma process uses an argon (Ar) plasma method, an N₂ plasma method, or an NH₃ plasma method.

17. The method of claim 14, wherein the forming of the epitaxial passivation layer comprises:
an operation of depositing a material of the epitaxial passivation layer using an atomic layer deposition method;
heating and crystallizing the deposited material of the epitaxial passivation layer; and
repeating the depositing of the material of the epitaxial passivation layer and the crystallizing of the deposited material of the epitaxial passivation layer a plurality of times.

18. The method of claim 14, wherein the surface activation layer has a thickness in a range of about 1 nm to about 5 nm.

19. The method of claim 14, wherein the surface activation layer comprises InGaN and AlN.

20. The method of claim 17, wherein the operation of depositing the material of the epitaxial passivation layer is performed in range of 1 to 10 times.
